(19) United States
(12) Patent Application Publication
(10) Pub. No.: US 2024/0012256 A1
(43) Pub. Date: Jan. 11, 2024

(54) Head-Mounted Display

(71) Applicant: APPLE INC., Cupertino, CA (US)

(72) Inventors: Paul X. Wang, Cupertino, CA (US); John Cagle, San Jose, CA (US)

(21) Appl. No.: 18/209,589

(22) Filed: Jun. 14, 2023

Related U.S. Application Data
(60) Provisional application No. 63/358,895, filed on Jul. 7, 2022.

(51) Int. Cl. G02B 27/01; H05K 7/20

(52) U.S. Cl. CPC G02B 27/0176; H05K 7/20954; G02B 2027/0154; G02B 2027/0161

(57) ABSTRACT

A head-mounted display device includes a device housing and a fan coupled to the device housing and configured to direct airflow within the device housing. The fan includes a fan housing, a motor hub, and a fan blade coupled to the motor hub. The fan blade has a first cross-section adjacent to the motor hub, a second cross-section outward of and adjacent to the first cross-section, and the first cross-section is smaller than the second cross-section such that an applied force to the device housing causes the fan blade to transition from an operable configuration to an inoperable configuration by deformation of the fan blade at the first cross-section.

### CROSS-REFERENCE TO RELATED APPLICATION(S)

This application claims priority to and the benefit of U.S. Provisional Patent Application No. 63/358,895, filed Jul. 7, 2022, the entire disclosure of which is incorporated by reference herein.

### FIELD

The present disclosure relates generally to the field of head-mounted displays.

### BACKGROUND

A head-mounted display is worn on the head of the user and provides graphical content to the user. The components of the head-mounted display are positioned in close proximity with little space to absorb energy from an applied force.

### SUMMARY

A first aspect of the disclosure according to one implementation is a head-mounted display device. The head-mounted display device includes a device housing and a fan coupled to the device housing. The fan is configured to direct airflow within the device housing. The fan includes a fan housing, a motor hub, and a fan blade coupled to the motor hub. The fan blade has a first cross-section adjacent to the motor hub, a second cross-section outward of and adjacent to the first cross-section, and the first cross-section is smaller than the second cross-section such that an applied force to the device housing causes the fan blade to transition from an operable configuration to an inoperable configuration by deformation of the fan blade at the first cross-section.

In some implementations according to the first aspect, the first cross-section of the fan blade is defined within a first plane perpendicular to a line extending along the fan blade from the motor hub to a tip of the fan blade and the second cross-section of the fan blade is defined within a second plane perpendicular to the line extending along the fan blade from the motor hub to the tip of the fan blade.

In some implementations according to the first aspect, the fan blade has an upper end positioned near an upper portion of the motor hub and the fan blade is connected to the motor hub adjacent to a lower portion of the motor hub such that the applied force to the device housing is transferred to the upper end of the fan blade to induce rotation of the fan blade around a line extending through the first cross-section.

In some implementations according to the first aspect, a cross-sectional area of the fan blade at the second cross-section is at least two times a cross-sectional area of the fan blade at the first cross-section.

In some implementations according to the first aspect, a cross-sectional area of the fan blade at the second cross-section is at least 70 percent of a maximum cross-sectional area of the fan blade.

In some implementations according to the first aspect, the first cross-section and the second cross-section are located within a first 10 percent of a length of the fan blade as measured from motor hub toward a tip of the fan blade.

In some implementations according to the first aspect, the fan blade is in the operable configuration when the fan blade rotates within the fan housing to direct airflow within the device housing and the fan blade is in the inoperable configuration when the fan blade cannot rotate to direct airflow within the device housing.

In some implementations according to the first aspect, the transition from the operable configuration to the inoperable configuration includes separation of the fan blade from the motor hub.

In some implementations according to the first aspect, the transition from the operable configuration to the inoperable configuration includes the fan blade twisting at the first cross-section.

In some implementations according to the first aspect, the fan blade is a first fan blade and the fan housing includes a second fan blade coupled to the motor hub. The second fan blade has a narrowed cross-section at a connection between the second fan blade and the motor hub. The first fan blade twists relative to the motor hub at the first cross-section adjacent to the motor hub to the inoperable configuration and the second fan blade twists relative to the motor hub at the narrowed cross-section between the second fan blade and the motor hub to the inoperable configuration in reaction to the applied force to the device housing.

In some implementations according to the first aspect, the first fan blade nests adjacent to the second fan blade after the first fan blade twists at the first cross-section and the second fan blade twists at the narrowed cross-section.

In some implementations according to the first aspect, the motor hub includes a side surface including at least one opening such that the motor hub is crushable from a first configuration having a first motor height to a second configuration having a second motor height that is less than the first motor height.

In some implementations according to the first aspect, the fan housing defines an interior space that includes an air guide member to direct air between an opening in the fan housing and the fan blade. The air guide member is coupled to the fan housing at a first end having a reduced cross-sectional area such that the air guide member is configured to deform to absorb energy of the applied force to the device housing. The deformation of the air guide member includes at least one of separation of the air guide member from the fan housing or twisting of the air guide member relative to the fan housing.

A second aspect of the disclosure according to one implementation of a head-mounted display device includes a device housing and a fan coupled to the device housing. The fan is configured to direct airflow within the device housing. The fan including a fan housing, a motor hub, and a fan blade coupled to the motor hub. The fan blade has a first cross-section adjacent to the motor hub, a second cross-section outward of and adjacent to the first cross-section, and the first cross-section is smaller than the second cross-section such that an applied force to the device housing causes the fan blade to transition from an operable configuration to an inoperable configuration by deformation of the fan blade at the first cross-section. The fan housing includes a deformable sidewall such that the deformation of the sidewall of the fan housing absorbs an energy of the applied force.

In some implementation according to the second aspect, the sidewall includes a notch extending at least partially through an exterior surface of the fan housing such that a first radial thickness of the sidewall is less than a second radial thickness of the sidewall. The applied force to the device housing causes the fan housing to deform at the notch from a first configuration in which the fan housing has a first height to a second configuration in which the fan housing has a second height that is less than the first height such that the deformation of the fan housing absorbs an energy of the applied force.

In some implementations according to the second aspect, the sidewall includes a first portion having a first cross-section and a second portion having a second cross-section that is smaller than the first cross-section. The fan housing is deformable, by pivoting at the second portion, from a first configuration in which the sidewall extends in an axial direction of the fan housing to a second configuration in which the sidewall extends in a direction angled from the axial direction of the fan housing.

In some implementations according to the second aspect, the sidewall connects an upper fan housing and a lower fan housing. The sidewall includes a first angled cutout such that a cross-section of the sidewall varies between the upper fan housing and the lower fan housing such that the upper fan housing rotates and translates relative to the lower fan housing in response to the applied force to the device housing.

A third aspect of the disclosure according to one implementation is a head-mounted display device. The head-mounted display device includes a device housing and a fan coupled to the device housing and configured to direct airflow within the device housing. The fan includes a fan housing, a motor hub, and a fan blade coupled to the motor hub. The head-mounted display device also includes a circuit board coupled to the device housing and adjacent to the fan. The circuit board has an edge defining an opening that is longitudinally aligned with the motor hub of the fan. An applied force to the device housing causes at least part of the motor hub to move from a first position within the fan housing to a second position within the opening in the circuit board.

In some implementations according to the third aspect, the opening is a recess in the circuit board. In some implementations according to the third aspect, the opening extends through the circuit board. In some implementations according to the third aspect, the motor hub of the fan moves relative to the circuit board in response to the applied force to the device housing.

A fourth aspect of the disclosure according to one implementation is a head-mounted display. The head-mounted display includes a support, an adjustment member coupled to the support and extending from a first side of the support, and a display assembly movably coupled to the adjustment member and configured to output graphical content to a user. An applied force to the display assembly causes rotation of the display assembly relative to the support by deformation of the adjustment member adjacent to the support.

In some implementations according to the fourth aspect, the applied force to the display assembly causes separation of the adjustment member from the support.

In some implementations according to the fourth aspect, the adjustment member includes a first cross-section adjacent to the support and a second cross-section outward of and adjacent to the first cross-section. The first cross-section is smaller than the second cross-section and the adjustment member is configured to deform at the first cross-section in response to the applied force.

In some implementations according to the fourth aspect, the adjustment member tapers from the second cross-section to the first cross-section.

In some implementations according to the fourth aspect, the head-mounted display further includes a second adjustment member coupled to the support and extending from a second side of the support and a second display assembly movably coupled to the second adjustment member and configured to output graphical content to the user. An applied force to the second display assembly causes rotation of the second display assembly relative to the support by deformation of the second adjustment member.

A fifth aspect of the disclosure according to one implementation is a head-mounted display device that includes a device housing having a front surface and a sidewall extending around a periphery of the front surface and a cover connected to the device housing. The cover is configured to cover the front surface and at least a portion of the sidewall of the device housing. The cover includes a protective member that extends from the cover away from the device housing and is configured to deform upon an applied force to the device housing to absorb an energy of the applied force.

In some implementations according to the fifth aspect, the protective member is positioned adjacent to an edge between the front surface and the sidewall of the device housing such that the protective member is a forward-pointing extension of the sidewall of the device housing.

In some implementations according to the fifth aspect, the cover is a rigid material and the protective member is a crushable material. In some implementations according to the fourth aspect, the cover is resiliently flexible and the protective member is non-resilient.

In some implementations according to the fifth aspect, the protective member is discontinuous around a periphery of the cover.

### BRIEF DESCRIPTION OF THE DRAWINGS

FIG. 1 is a schematic exploded cross-sectional illustration of a head-mounted display, according to an implementation.

FIG. 2 is a schematic illustration of a fan and a circuit board of the head-mounted display of FIG. 1.

FIG. 3 is a schematic perspective view of the circuit board of FIG. 2, according to an implementation.

FIG. 4 is a schematic cross-sectional illustration of a motor hub of a fan for a head-mounted display and a circuit board of the head-mounted display, according to an implementation.

FIG. 5 is a schematic illustration of a motor hub in a first configuration, according to an implementation.

FIG. 6 is a schematic illustration of the motor hub of FIG. 5 in a second configuration, according to an implementation.

FIG. 7 is a schematic cross-sectional illustration of a motor hub and fan blade assembly, according to an implementation.

FIG. 8 is a schematic cross-sectional illustration of a fan blade, according to an implementation.

FIG. 9 is a schematic plan view of a motor hub and fan blade assembly, according to an implementation.

FIG. 10 is a schematic illustration of a motor hub and fan blade assembly in a first configuration, according to another implementation.

FIG. 11 is a schematic illustration of the motor hub and fan blade assembly of FIG. 10 in a second configuration.

FIG. 12 is a schematic illustration of a motor hub and fan blade assembly in a first configuration, according to another implementation.

FIG. 13 is a schematic illustration of the motor hub and fan blade assembly of FIG. 12 in a second configuration.

FIG. 14 is a schematic illustration of a fan housing assembly, according to an implementation.

FIG. 15 is a schematic illustration of a fan housing assembly, according to another implementation.

FIG. 16 is a schematic illustration of a fan housing assembly including an air guide, according to an implementation.

FIG. 17 is a schematic illustration of an optical module adjustment assembly for a head-mounted display, according to an implementation.

FIG. 18 is a schematic illustration of a cover for a head-mounted display, according to an implementation.

FIG. 19 is a schematic cross-sectional illustration of the cover of FIG. 18.

### DETAILED DESCRIPTION

The disclosure herein relates to head-mounted displays and components thereof. In many implementations, the space between the components of the head-mounted display is very small, and the components themselves are inflexible and unable to absorb energy from an event, such as a force applied to the housing of the head-mounted display from dropping the head-mounted display, for example. The head-mounted displays discussed throughout this disclosure include components that can deform in response to an applied force to the head-mounted display. In some implementations, the head-mounted displays include components having fused breakage areas that permit relative motion between the components.

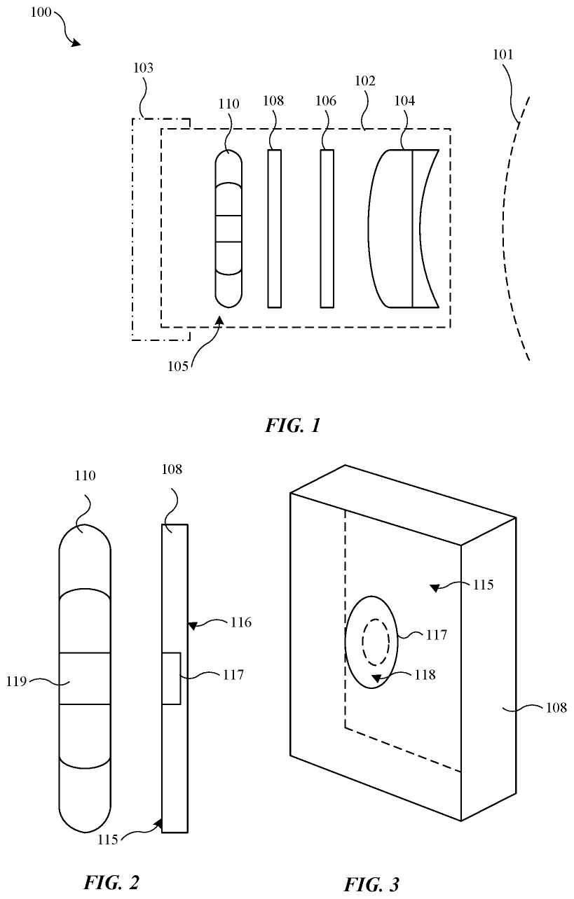

With reference to FIG. 1, a head-mounted display 100 generally includes a device housing 102 and a cover 103 that covers a front surface and at least a portion of a sidewall of the device housing 102. An optical module 104, a first display 106, a printed circuit board 108, and a fan assembly 110, which collectively make up a display assembly 105 of the head-mounted display 100, are coupled to the device housing 102. The head-mounted display 100 is configured to be worn on a head of a user 101 with two display assemblies 105 positioned to display graphical content to the eyes of the user 101. The device housing 102 is a chassis that supports the display assemblies 105, including each of the components of the display assembly 105 (e.g., the optical module 104, a first display 106, a printed circuit board 108, and a fan assembly 110).

The optical module 104 includes at least one lens. The lens of the optical module 104 refracts light emitted from the first display 106 before reaching the eye of the user 101.

Adjacent to and forward (e.g., away from the user 101) of the optical module 104 is the first display 106. The first display 106 is configured to display graphical content to the user 101. In various implementations, the head-mounted display 100 includes the first display 106 positioned forward (e.g., outward or away from the user 101) of the optical module 104. In various implementations, the first display 106 is adjacent to the optical module 104; however, in other implementations, other components of the head-mounted display 100 are positioned between the first display 106 and the optical module 104.

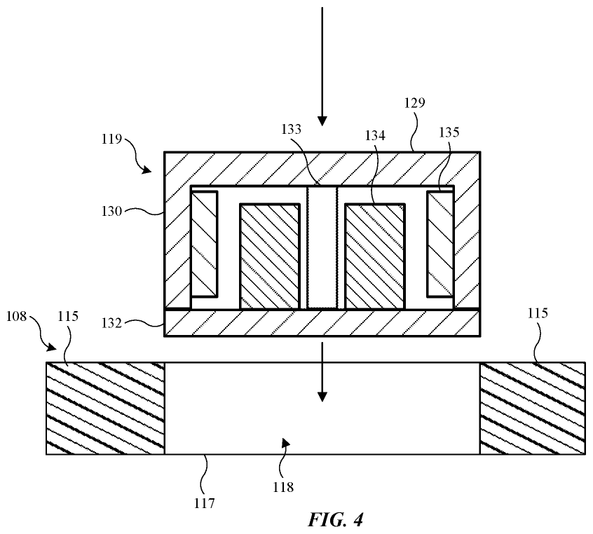

In some implementations, the printed circuit board 108 is coupled to the device housing 102 and is positioned adjacent to and forward of the first display 106. With reference to FIGS. 2 and 3, in some implementations, the printed circuit board 108 includes an edge 117 that defines an opening 118. The printed circuit board 108 (e.g., PCB), is a non-conductive material on which conductive lines are printed or etched. Electronic components are mounted on the printed circuit board 108 and the conductive lines or traces connect the components together to form a working circuit or assembly. In various implementations, the electronic components and conductive lines or traces are arranged around the opening 118. The opening 118 is, in some implementations, a recess in the printed circuit board 108. In other implementations, the opening 118 extends through the printed circuit board 108 from a front surface 115 (e.g., first surface) of the printed circuit board 108 to a rear surface 116 (e.g., second surface) of the printed circuit board 108.

The fan assembly 110 is positioned forward of and adjacent to the printed circuit board 108, in some implementations. The fan assembly 110 includes a motor hub 119 and at least one fan blade coupled to the motor hub 119, as discussed in greater detail herein. In some embodiments, the motor hub 119 is an electric motor. As shown in FIG. 2, the opening 118 in the printed circuit board 108 is longitudinally aligned with the motor hub 119 of the fan assembly 110.

With reference now to FIG. 4, the motor hub 119 is an electric motor hub that includes a motor housing 128 having a top surface 129, a side surface 130, and a bottom surface 132. The motor hub 119 as shown in FIG. 4 is a coil and magnet electric motor. An axle 133 is coupled to the motor housing 128. A coil 134 is wrapped around the axle 133 and a magnet 135 is coupled to the motor housing 128 outward of the coil 134. In various implementations, the coil 134 is a coil of wire, such as copper. In various implementations, the axle 133 is made of plastic or fiberglass.

An electric current induced in the coil 134 emits a magnetic field, which opposes the magnetic field emitted by the magnet 135. As a result, the axle 133 and coil 134 rotate relative to the magnet 135. A fan blade (not shown in FIG. 4) is coupled to the axle 133 and rotates with the axle.

An applied force to the device housing 102 results in movement of the components of the head-mounted display 100 relative to each other. Due to the small air gap within the device housing 102, the components have very little room to move to absorb the energy of the applied force. As illustrated by the arrows in FIG. 4, the applied force to the device housing 102 causes at least part of the motor hub 119 to move from a first position within the fan assembly 110 to a second position within the opening 118 in the printed circuit board 108. The opening 118 is illustrated in FIG. 4 as extending through the printed circuit board 108 from the front surface 115 to the rear surface 116. The opening 118 permits the motor hub 119, which is relatively rigid, to move relative to the printed circuit board 108 as the force is applied to the device housing 102. Since the motor hub 119 is not as deformable as surrounding components, such as, for example, a fan housing, the movement of the motor hub 119 to a second position within the device housing 102 and relative to the printed circuit board 108 can prevent or reduce damage to other components of the head-mounted display 100, such as the optical module 104 and first display 106, for example.

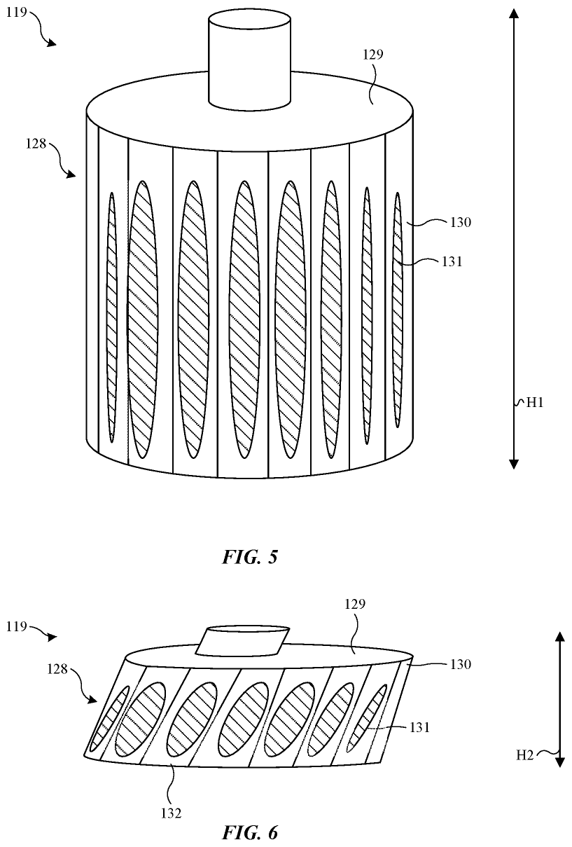

In some embodiments, the motor hub 119 includes openings 131 formed in the side surface 130 of the motor housing 128, as shown in FIGS. 5 and 6. The openings 131 may be cutouts, notches, slashes, etc. in the side surface 130 of the motor housing 128. In various implementations, the openings 131 are open, and in other implementations the openings 131 are filled with mesh or some other material different from the material of the motor housing 128. In some implementations, the openings 131 are filled with a plastic or metal mesh material that is more deformable than the material of the motor housing 128.

As shown in FIG. 5, the motor hub 119 is shown in a first configuration. In the first configuration, the motor hub 119 has a first motor height H1 that is defined as a height of the motor hub 119 prior to any deformation due to an applied force to the device housing 102. The motor hub 119 is in a generally upright configuration prior to deformation such as a crushing or collapsing.

A second configuration of the motor hub 119 is shown in FIG. 6. In the second configuration, the motor hub 119 has a second motor height H2 that is less than the first motor height H1. The motor housing 128 is illustrated in a deformed configuration (e.g., crushed or collapsed) as compared to the first configuration shown in FIG. 5. The openings 131 reduce the overall structural rigidity of the motor housing 128 and allow the side surface 130 to deform in a reversible manner, such as collapsing, or nonreversible manner, such as crushing. The motor hub 119 is reversibly or irreversibly deformable from the first configuration, shown in FIG. 5, to the second configuration, shown in FIG. 6.

In various implementations, as shown in FIG. 6, the top surface 129 can shift or move relative to the bottom surface 132. The shifting movement of the motor housing 128 is reversible in some implementations (e.g., the motor housing 128 can be manipulated by hand or by a mechanism to return to the original, pre-shifted configuration, such as the configuration shown in FIG. 5). The openings 131, whether open or filled with a less rigid material than the material of the motor housing 128, facilitate deformation and/or movement of the side surface 130 of the motor housing 128 in response to the compression of the applied force to the device housing 102 as the openings 131 reduce the overall resistance of the motor housing 128 to a compressive force such as the applied force.

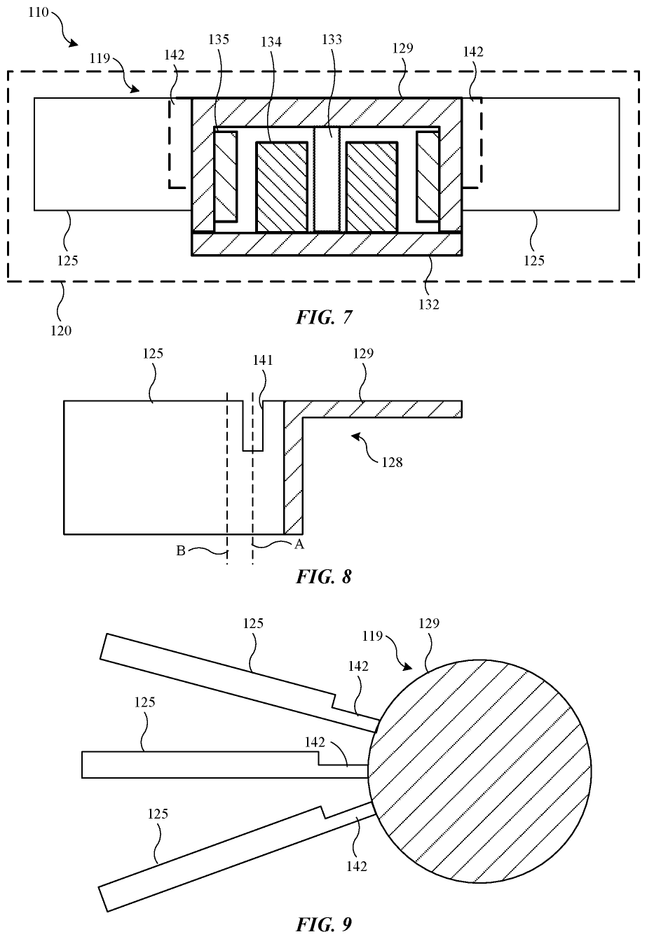

The motor hub 119 is one component of the fan assembly 110. As shown in FIG. 7, the fan assembly 110 includes a fan housing 120, the motor hub 119, and a fan blade 125 coupled to the motor hub 119. The fan assembly 110 is coupled to the device housing 102, as shown in FIG. 1, and is configured to direct airflow within the device housing 102.

As discussed herein with respect to FIG. 4, the motor hub 119 is an electric motor that includes the coil 134 wrapped around the axle 133. An electric current passing through the coil 134 generates a magnetic field that interacts with the magnetic field generated by the magnet 135 to induce rotation of the axle 133 and coil 134. The fan blade 125 is coupled to the axle 133 such that the fan blade 125 rotates with the axle 133. The fan assembly 110 can include one, two, three, or more fan blades 125. FIG. 7 illustrates a fan blade 125 and a fan blade 125 coupled to either side of the motor hub 119.

Each fan blade 125 has a fused breakage location 142 adjacent to (e.g., proximal or next to) the motor hub 119. The fused breakage location 142 is a narrowing or thinning of a cross-section of the fan blade 125 in a plane perpendicular to a line extending along the fan blade 125 from the motor hub 119 to a tip of the fan blade 125. The fused breakage location 142 enables the fan blade 125 to move (e.g., rotate, separate, and/or deform) relative to the motor hub 119 upon application of an applied force to the device housing 102 due to the narrowing or narrowed cross-section at the fused breakage location 142.

FIG. 8 illustrates the fan blade 125 in a side cross-sectional view. An edge 141 formed in the top surface of the fan blade 125 forms a notch or area of a reduced cross-section in the fan blade 125 adjacent to the motor hub 119. The fan blade 125 has a first cross-section adjacent to the motor hub 119, located in a first plane A, and a second cross-section outward of and adjacent to the first cross-section, located in a second plane B. The first cross-section of the fan blade 125 is defined within the first plane A perpendicular to a line extending along the fan blade 125 from the motor hub 119 to a tip of the fan blade 125 and the second cross-section of the fan blade 125 is defined within the second plane B perpendicular to the line extending along the fan blade 125 from the motor hub 119 to the tip of the fan blade 125.

The first cross-section is smaller than the second cross-section such that an applied force to the device housing 102 causes the fan blade 125 to transition from an operable configuration to an inoperable configuration by deformation (e.g., twisting and/or separation) of the fan blade 125 at the first cross-section. In various implementations, a cross-sectional area of the fan blade 125 at the second cross-section is at least two times a cross-sectional area of the fan blade 125 at the first cross-section. In some implementations, a cross-sectional area of the fan blade 125 at the second cross-section is at least 70 percent of a maximum cross-sectional area of the fan blade 125. In some implementations, the first cross-section and the second cross-section are located within a first 10 percent of a length of the fan blade 125 as measured from motor hub 119 toward a tip of the fan blade 125. In various implementations, an area of the fan blade 125 at the first cross-section is at least 80 percent of a maximum cross-sectional area of the fan blade 125. In various implementations, an area of the fan blade 125 at the first cross-section is at least 90 percent of a maximum cross-sectional area of the fan blade 125. In some implementations, an area of the fan blade 125 at the first cross-section is between 70 percent and 90 percent of a maximum cross-sectional area of the fan blade 125. In some implementations, an area of the fan blade 125 at the first cross-section is at least one-third of an area of the fan blade 125 at the second cross-section. In some implementations, the first cross-section and the second cross-section are located within a first 5 percent of a length of the fan blade 125 as measured from motor hub 119 to a tip of the fan blade 125.

The fan blade 125 is in the operable configuration when the fan blade 125 rotates within the fan housing 120 to direct airflow within the device housing 102. The fan blade 125 is in the inoperable configuration when the fan blade 125 cannot rotate to direct airflow within the device housing 102, such as when the fan blade 125 is twisted relative to the motor hub 119 or has separated from the motor hub 119. Transition from the operable configuration to the inoperable configuration may include separation of the fan blade 125 from the motor hub 119 due to fracture or breakage at the first cross-section. Transition from the operable configuration to the inoperable configuration may also include the fan blade 125 twisting at the first cross-section relative to the motor hub 119 such that the fan blade 125 is no longer able to induce air movement throughout the device housing 102. To absorb the energy of the applied force to the device housing 102, the fan blade 125 twists at the first cross-section relative to the motor hub 119.

As seen in the top plan view shown in FIG. 9, the fan blade 125 has a fused breakage location 142 that is a narrowing or thinning cross-section adjacent to the motor hub 119. The fused breakage location 142 is, in some implementations, a narrowing of the cross-section of the fan blade 125 from the tip toward the connection with the motor hub 119. The fused breakage location 142 can be a gradual or graduated narrowing area toward the connection of the fan blade 125 with the motor hub 119. In some implementations, the fused breakage location 142 is a defined notch, as shown in FIG. 8, with an abrupt change in cross-section along the line extending along the fan blade 125 from the connection with the motor hub 119 to the tip of the fan blade 125.

With continued reference to FIG. 8, the fan blade 125 has an upper end positioned near an upper portion of the motor hub 119 and the fan blade 125 is connected to the motor hub 119 adjacent to a lower portion of the motor hub 119 such that the applied force to the device housing 102 is transferred to the upper end of the fan blade 125 to induce rotation of the fan blade 125 around a line extending through the first cross-section. The connection of the fan blade 125 to the motor hub 119 near the bottom surface of the motor hub 119 allows the fan blade 125 greater freedom to deform and twist relative to the motor hub 119 due to the smaller area of connection between the fan blade 125 and the motor hub 119.

The fan assembly 110 is a component of the head-mounted display 100 that includes areas of high stiffness, such as the motor hub 119, and areas of low stiffness, such as the fan blade 125. In response to an applied force to the head-mounted display 100, such a generally frontal force or force to the side of the head-mounted display 100, the components shift, move, and/or deform to absorb the energy of the applied force. The motor hub 119 is a stiff component that does not easily deform or crush. Thus, as shown in FIG. 4, in some implementations, the motor hub 119 moves as a unit to a second position within the device housing 102; in the illustrated implementation, the motor hub 119 is received in the opening 118 in the printed circuit board 108.

While the motor hub 119 is configured to move in response to the applied force, the fan blade 125 is configured to deform (e.g., twist, crush, and/or separate) relative to the motor hub 119. As discussed herein, the fan blade 125 has a discontinuous cross-section along a line extending from the motor hub 119 to the tip of the fan blade 125. The discontinuation is, in some implementations, a notch, as shown in FIG. 8, or a narrowing or thinning cross-section, as shown in FIG. 9. In both implementations, the smaller cross-section is proximal to the motor hub 119. When the force is applied to device housing 102 and is transferred to the fan assembly 110 through the movement or deformation of the outer components of the head-mounted display 100, the connection of the fan blade 125 with the motor hub 119 is a fused breakage location at which the fan blade 125 either elastically or inelastically deforms relative to a line extending through the small or first cross-section. The fan blade 125 does not rigidly resist the transferred force but rather twists or deforms to an inoperable configuration in response to the transferred force.

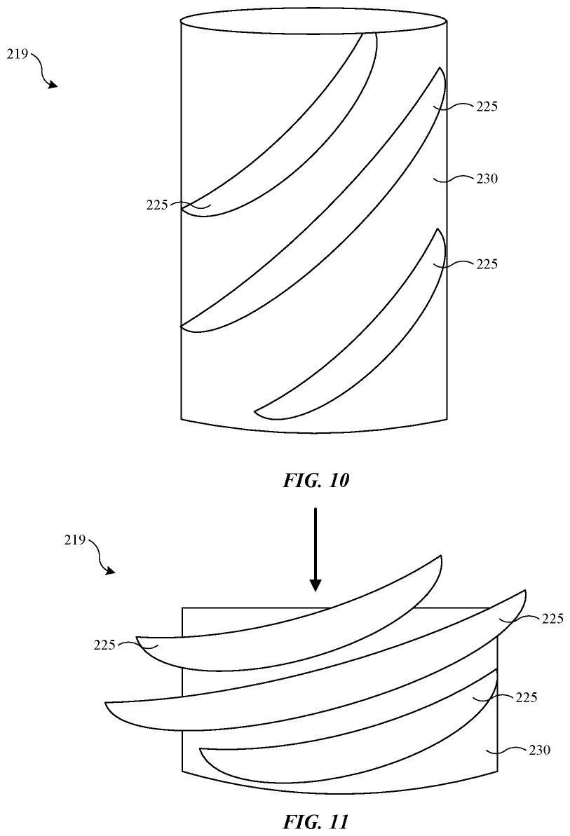

FIGS. 10 and 11 illustrate another implementation of a motor hub 219 for a fan assembly, such as the fan assembly 110. The motor hub 219 includes electrical components as described with respect to the motor hub 119 that enable rotation of a connected fan blade to distribute air throughout the device housing 102. In the implementation shown in FIGS. 10 and 11, the motor hub 219 includes a plurality of fan blades 225 that are coupled to the side surface 230 of the motor hub 119 at an angle. In some implementations, the angle of the fan blades 225 to a line extending through the center of the motor hub 219 is approximately 30 degrees. In other implementations, the fan blades 225 are coupled to the motor hub 219 at an angle of between 30 degrees and 50 degrees. The fan blades 225 may be connected to the motor hub 219 at a fused breakage location as discussed herein with respect to FIGS. 8 and 9.

In response to the applied force to the device housing 102, the motor hub 219 can deform or crush, such as the deformation of the motor hub 119 shown in FIG. 6. The fan blades 225 deform or twist as discussed herein such that the fan blades 225 nest together, as shown in FIG. 11. When nested together, the fan blades 225 are oriented more horizontally than when in the operable configuration shown in FIG. 10. A fan blade 225 nests adjacent to another fan blade 225 after the twisting of the fan blade 225 at the first or narrowed cross-section and the twisting of the other fan blade 225 at the second or narrowed cross-section.

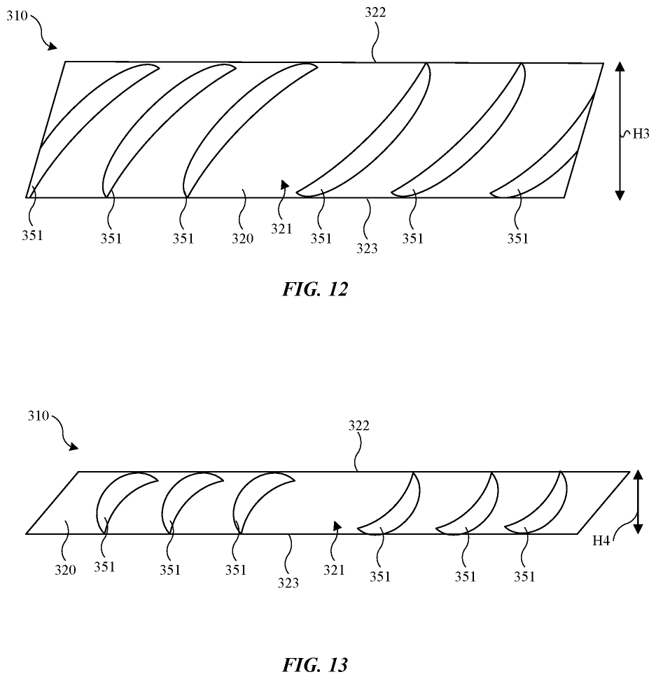

In another implementation, shown in FIGS. 12 and 13, a fan assembly 310 is illustrated as having a fan housing 320 that has a rhomboid-shaped configuration. While not shown, the fan assembly 310 includes a motor hub, such as the motor hub 119, and a fan blade 125, as discussed herein. The fan housing 320 includes one or more openings 351 in the side surface 321 (i.e., sidewall) of the fan housing 320. The openings 351 facilitate deformation of the fan housing 320 upon application of the force applied to the device housing 102 by reducing the rigidity of the fan housing 320 such that the fan housing 320 can deform to a flattened shape, as illustrated in FIG. 13. Similar to the openings 131 discussed herein with respect to the motor hub 119, the openings 351 in the fan housing 320 may be open (i.e., not filled) or filled with a less rigid material than the material of the fan housing 320. The openings 351 facilitate deformation and/or movement of the side surface 321 of the fan housing 320 in response to the compression of the applied force to the device housing 102 as the openings reduce the overall resistance of the fan housing 320 to a compressive force such as the applied force. As shown in FIG. 13, a top surface 322 (e.g., upper fan housing) of the fan housing 320 shifts relative to a bottom surface 323 (e.g., lower fan housing) of the fan housing 320 in response to the compression of the applied force to the device housing 102. The rhomboid shape of the fan housing 320, along with the openings 351, reduce the rigidity of the fan housing 320 such that the fan housing 320 responds to a compressive force by collapsing into the flattened rhomboid shape shown in FIG. 13.

In various implementations, the fan housing 320 is made from a rigid material such as plastic or metal, which can elastically or inelastically deform from the operable configuration shown in FIG. 12 to the inoperable configuration shown in FIG. 13. The fan housing 320 may be reversible from the inoperable configuration to the operable configuration by manipulation of the fan housing 320 by hand or machine to unfold or reform the fan housing 320 to the operable configuration.

The fan housing 320 shown in FIG. 12 has a first fan height H3 defined as the fan height when the fan assembly 310 is in an operable configuration prior to any deformation due to an applied force to the device housing 102. The fan housing shown in FIG. 13 has a second fan height H4 defined as the fan height when the fan assembly 310 is in an inoperable configuration after deformation. The second fan height H4 is less than the first fan height H3.

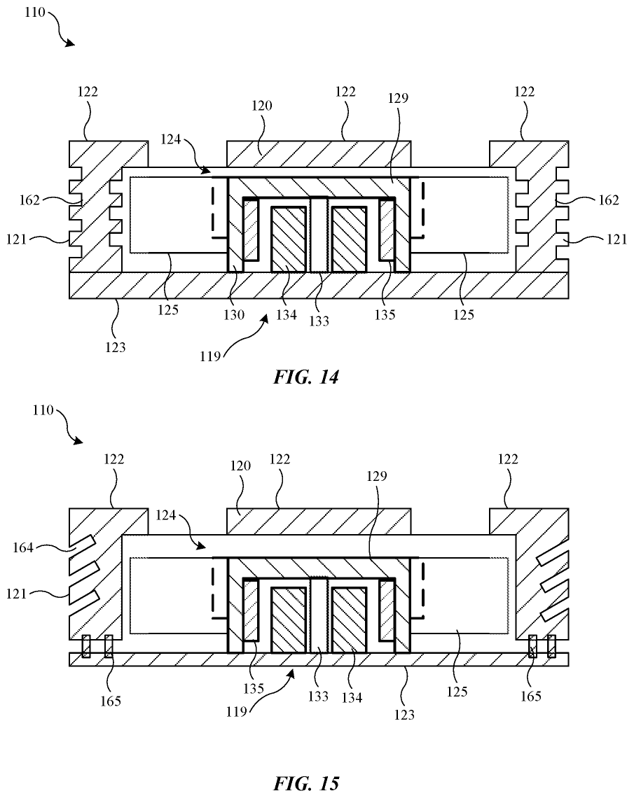

FIGS. 14 and 15 each illustrate a cross-section of the fan assembly 110, according to two implementations of a sidewall 121 of the fan assembly 110. The fan assembly 110 includes a fan housing 120 that includes the sidewall 121, an upper fan housing 122, and a lower fan housing 123. Together, the sidewall 121, the upper fan housing 122, and the lower fan housing 123 define a fan housing interior space 124. The motor hub 119 is positioned within the fan housing interior space 124 and is illustrated as discussed herein with a connection to two fan blades 125.

In some implementations, as shown in FIG. 14, the fan housing 120 includes a notch 162 (e.g., cutout) extending at least partially through an exterior surface of the fan housing, such as a sidewall 121 of the fan housing 120. The sidewall 121 of the fan housing 120 shown in FIG. 14 has a serrated configuration (e.g., notches or cutouts occur on both an exterior-facing surface of the sidewall 121 and on an interior-facing surface of the sidewall 121). The sidewall 121 may include a plurality of notches 162 extending from the upper fan housing 122 to the lower fan housing 123. A first radial thickness of the sidewall 121 measured at the notch 162 is less than a second radial thickness of the sidewall 121 measured adjacent to the notch 162. In reaction to the applied force to the device housing 102, the fan housing 120 deforms at the notch 162 from a first configuration in which the fan housing 120 has a first height to a second configuration in which the fan housing 120 has a second height that is less than the first height such that the deformation of the fan housing 120 absorbs an energy of the applied force.

With reference to FIG. 15, the sidewall 121 includes a cutout 164 that extends at least partially through the exterior surface of the sidewall 121 of the fan housing 120. The cutout 164 is formed on an angle with a line extending radially through the fan housing 120. The cutout 164 may make a first angle with the line extending radially through the fan housing 120 on a first side of the fan housing 120 and make a second angle with the line extending radially through the fan housing 120 on a second or opposite side of the fan housing 120. The sidewall 121 may include a plurality of cutouts 164 extending from the upper fan housing 122 to the lower fan housing 123.

The notches 162 and the cutouts 164 reduce the structural rigidity of the fan housing 120 such that the fan housing 120 deforms to absorb energy from the applied force to the device housing 102. The notches 162 and cutouts 164 enable the fan housing 120 to flatten or compress in response to the compressive force.

The cutout 164 is a first angled cutout such that a cross-section of the sidewall 121 varies between the upper fan housing 122 and the lower fan housing 123. The upper fan housing 122 rotates and translates relative to the lower fan housing 123 in response to the applied force to the device housing 102.

In the implementation shown in FIG. 15, the sidewall 121 of the fan housing 120 includes a first portion having a first cross-section and a second portion having a second cross-section that is smaller than the first cross-section (e.g., the second portion includes the cutout 164). The fan housing 120 is deformable, by pivoting at the second portion, from a first configuration in which the sidewall 121 extends in an axial direction of the fan housing 120 to a second configuration in which the sidewall 121 extends in a direction angled from the axial direction of the fan housing 120.

In some implementations, the lower fan housing 123 of the fan housing 120 is attached to the sidewall 121 via one or more hinges 165. The hinge 165 allows rotation of the sidewall 121 relative to the lower fan housing 123, as shown in FIG. 13 and discussed herein. In various implementations, the hinge 165 allows for reversible deformation of the fan housing 120 (e.g., the sidewall 121 of the fan housing 120 can collapse in response to the applied force but is reversible to an operable configuration via rotation of the hinge 165).

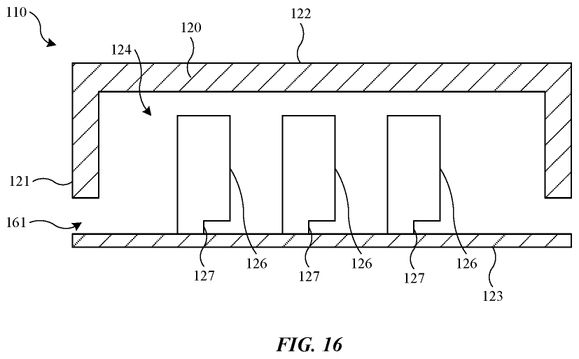

With reference to FIG. 16, in some implementations, the fan housing 120 includes an air guide member 126 positioned within the fan housing interior space 124 of the fan housing 120. The air guide member 126 directs air within the fan housing interior space 124 of the fan housing 120 between an opening 161 in the fan housing 120 and the fan blade 125. The air guide member 126 includes features similar to those discussed herein with regard to the fan blade 125, that is, the air guide member 126 is coupled to the fan housing 120 at a first end that has a reduced cross-sectional area 127. Each air guide member 126 has a fused breakage location adjacent to (e.g., proximal or next to) the lower fan housing 123. The fused breakage location is a narrowing or thinning of a cross-sectional area 127 of the air guide member 126 in a plane perpendicular to a line extending along the air guide member 126 from the lower fan housing 123 to a tip of the air guide member 126. The fused breakage location enables the air guide member 126 to move (e.g., rotate, separate, and/or deform) relative to the lower fan housing 123 upon application of an applied force to the device housing 102 due to the narrowing or narrowed cross-sectional area 127.

Similar to the fan blade 125, the air guide member 126 is deformable by twisting relative to or separation from the fan housing 120 at the reduced cross-sectional area 127. The deformation of the air guide member 126 absorbs the energy of the applied force to the device housing 102.

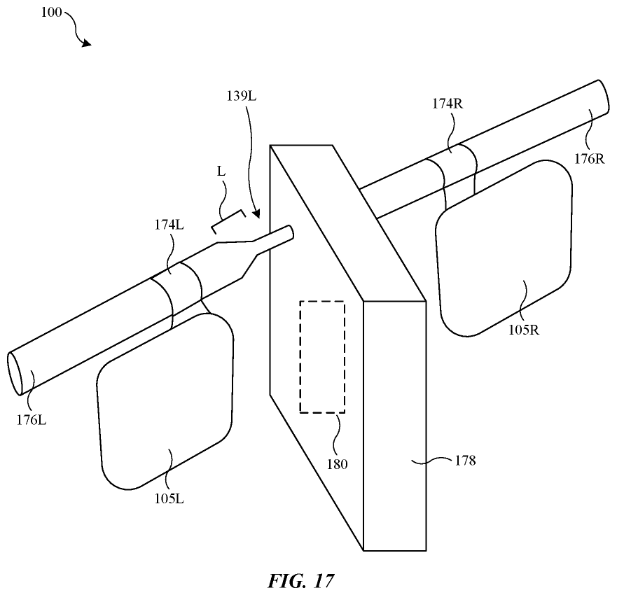

In another implementation of a head-mounted display 100, shown in FIG. 17, a first display assembly 105L is positioned in front of one eye, a second display assembly 105R is positioned in front of the other eye, and each of the first display assembly 105L and the second display assembly 105R is coupled to a support 178 at a fused breakage location. The fused breakage location allows the display assembly 172 to bend, twist, or separate from the support 178 in response to an applied force. The head-mounted display 100 includes a first display assembly 105L configured to output graphical content and a second display assembly 105R configured to output graphical content. The first display assembly 105L is movably coupled to a first adjustment member 176L with a first connecting member 174L. The first adjustment member 176L extends from a first side of the support 178.

The second display assembly 105R is movably coupled to a second adjustment member 176R with a second connecting member 174R. The second adjustment member 176R extends from a second side of the support 178. The second side of the support 178 is opposite the first side of the support 178.

In various implementations, the support includes an interpupillary distance mechanism 180. The interpupillary distance mechanism 180 is configured to adjust a distance between the first display assembly 105L and the second display assembly 105R based on an interpupillary distance measured between the left eye and the right eye. Upon receipt of a command the interpupillary distance mechanism 180 can adjust the distance between the first display assembly 105L and the second display assembly 105R by moving one or both of the first adjustment member 176L and the second adjustment member 176R. The movement of one or both of the first adjustment member 176L and the second adjustment member 176R adjusts an overall length of each of the first adjustment member 176L and the second adjustment member 176R as measured from the support 178 to the tip of each of the first adjustment member 176L and the second adjustment member 176R.

An applied force to the device housing 102 is transferred to the first display assembly 105L and causes rotation of the first display assembly 105L relative to the support 178 by deformation of the first adjustment member 176L adjacent to the support 178. Similarly, an applied force to the device housing 102 can be transferred to the second display assembly 105R and causes rotation of the second display assembly 105R relative to the support 178 by deformation of the second adjustment member 176R adjacent to the support 178. In various implementations, the applied force to the device housing 102 is a force applied to the front or side of the device housing 102. The applied force is then transferred to the first display assembly 105L and/or the second display assembly 105R.

The first adjustment member 176L includes a first cross-section 139L adjacent to the support 178 and a second cross-section outward of and adjacent to the first cross-section 139L. The first cross-section 139L is smaller than the second cross-section. The first adjustment member 176L is configured to deform (e.g., twist, bend, or separate) at the first cross-section 139L in response to the applied force. The first adjustment member 176L tapers from the second cross-section to the first cross-section 139L along a length L of the first adjustment member 176L.

While not shown in FIG. 17, the second adjustment member 176R includes a reduced cross-section adjacent to the support 178 and a cross-section outward of the reduced cross-section that is larger than the reduced cross-section. The second adjustment member 176R is configured to deform (e.g., bend, twist, or separate) at the reduced cross-section in response to the applied force. While hidden by the support 178, the second adjustment member 176R tapers from a larger cross-section to the reduced cross-section adjacent to the support 178.

In various implementations, the first cross-section 139L includes a tapering or narrowing of the cross-section of the first adjustment member 176L from a larger cross-section (e.g., a second cross-section) outward of and distal from the support 178 to a narrower or thinner cross-section (e.g., a first cross-section) adjacent and proximal to the support 178. Similarly, the reduced cross-section of the second adjustment member 176R includes a narrowing or tapering of the cross-section from a larger cross-section outward of and distal from the support to a narrower or thinner cross-section adjacent and proximal to the support 178.

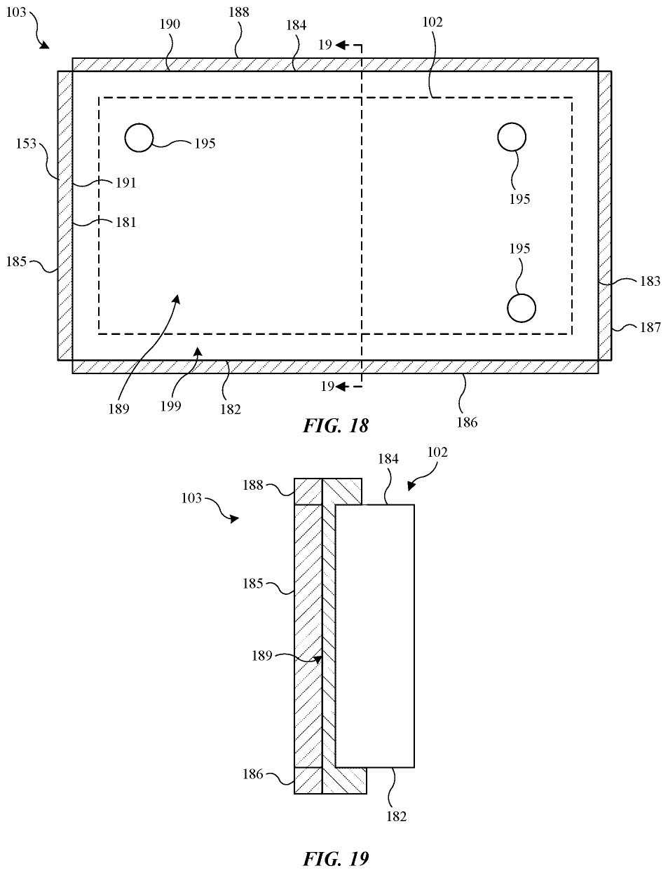

As shown schematically in FIG. 1, the head-mounted display 100 includes, in some implementations, a cover 103. The cover 103 is shown in greater detail in FIGS. 18 and 19. The device housing 102 has a front surface 189 and a sidewall 190 including a first side 181, a bottom 182, a second side 183, and a top 184. The first side 181, the bottom 182, the second side 183, and the top 184 form a sidewall 190 that is a continuous surface that extends around the periphery of the front surface 189 of the device housing 102.

The cover 103 is connected to the device housing 102 such that the cover 103 covers the front surface 189 and at least a portion of the sidewall 190 of the device housing 102. The cover 103 includes a front cover surface 199 and a protective member 153 that extends from the front cover surface 199 of the cover 103 away from the device housing 102. The protective member 153 includes, in some implementations, a first extended portion 185, a second extended portion 186, a third extended portion 187, and a fourth extended portion 188 and is continuous around a periphery of the front surface 189 of the device housing 102. In other implementations, the protective member 153 is discontinuous around the periphery of the front surface 189, that is, either the protective member 153 does not include all four extended portions or there is a gap between each of the extended portions.

The first extended portion 185 extends outward from the device housing 102 and is positioned adjacent to an edge 191 that extends around the front surface 189 and between the front surface 189 and the sidewall 190. The first extended portion 185 is adjacent to the first side 181 of the device housing 102. The second extended portion 186 extends outward from the device housing 102 and is positioned adjacent to the edge 191 that extends around the front surface 189 and between the front surface 189 and the sidewall 190. The second extended portion 186 is adjacent to the bottom 182 of the device housing 102. The third extended portion 187 extends outward from the device housing 102 and is positioned adjacent to the edge 191 that extends around the front surface 189 and between the front surface 189 and the sidewall 190. The third extended portion 187 is adjacent to the second side 183 of the device housing 102. The fourth extended portion 188 extends outward from the device housing 102 and is positioned adjacent to the edge 191 that extends around the front surface 189 and between the front surface 189 and the sidewall 190. The fourth extended portion 188 is adjacent to the top 184 of the device housing 102.

The protective member 153 is a forward-pointing extension of the sidewall 190 of the device housing 102 and is configured to deform upon an applied force to the device housing 102. The protective member 153 is formed from a crushable material such as plastic such that the protective member 153 absorbs energy from the applied force to the device housing 102. The front cover surface 199 is formed from a rigid material such as plastic or glass that is translucent (i.e., transparent) in some implementations. In some implementations, the front cover surface 199 is opaque. A plurality of openings 195 are formed through the front cover surface 199 to permit sensors of the head-mounted display 100 to observe the ambient environment.

In various implementations, the portions of the cover 103 that cover the front surface 189 and the portion of the sidewall 190 of the device housing 102 are resiliently flexible, that is, deformable but able to return to their original shape or configuration. The protective member 153 is non-resilient, that is, the protective member 153 deforms to absorb the energy from the applied force and is not able to be manipulated back to its original configuration prior to deformation.

A physical environment refers to a physical world that people can sense and/or interact with without aid of electronic systems. Physical environments, such as a physical park, include physical articles, such as physical trees, physical buildings, and physical people. People can directly sense and/or interact with the physical environment, such as through sight, touch, hearing, taste, and smell.

In contrast, a computer-generated reality (CGR) environment refers to a wholly or partially simulated environment that people sense and/or interact with via an electronic system. In CGR, a subset of a person's physical motions, or representations thereof, are tracked, and, in response, one or more characteristics of one or more virtual objects simulated in the CGR environment are adjusted in a manner that comports with at least one law of physics. For example, a CGR system may detect a person's head turning and, in response, adjust graphical content and an acoustic field presented to the person in a manner similar to how such views and sounds would change in a physical environment. In some situations (e.g., for accessibility reasons), adjustments to characteristic(s) of virtual object(s) in a CGR environment may be made in response to representations of physical motions (e.g., vocal commands).

A person may sense and/or interact with a CGR object using any one of their senses, including sight, sound, touch, taste, and smell. For example, a person may sense and/or interact with audio objects that create three-dimensional or spatial audio environment that provides the perception of point audio sources in three-dimensional space. In another example, audio objects may enable audio transparency, which selectively incorporates ambient sounds from the physical environment with or without computer-generated audio. In some CGR environments, a person may sense and/or interact only with audio objects.

Examples of CGR include virtual reality and mixed reality.

A virtual reality (VR) environment refers to a simulated environment that is designed to be based entirely on computer-generated sensory inputs for one or more senses. A VR environment comprises a plurality of virtual objects with which a person may sense and/or interact. For example, computer-generated imagery of trees, buildings, and avatars representing people are examples of virtual objects. A person may sense and/or interact with virtual objects in the VR environment through a simulation of the person's presence within the computer-generated environment, and/or through a simulation of a subset of the person's physical movements within the computer-generated environment.

In contrast to a VR environment, which is designed to be based entirely on computer-generated sensory inputs, a mixed reality (MR) environment refers to a simulated environment that is designed to incorporate sensory inputs from the physical environment, or a representation thereof, in addition to including computer-generated sensory inputs (e.g., virtual objects). On a virtuality continuum, a mixed reality environment is anywhere between, but not including, a wholly physical environment at one end and virtual reality environment at the other end.

In some MR environments, computer-generated sensory inputs may respond to changes in sensory inputs from the physical environment. Also, some electronic systems for presenting an MR environment may track location and/or orientation with respect to the physical environment to enable virtual objects to interact with real objects (that is, physical articles from the physical environment or representations thereof). For example, a system may account for movements so that a virtual tree appears stationary with respect to the physical ground.

Examples of mixed realities include augmented reality and augmented virtuality.

An augmented reality (AR) environment refers to a simulated environment in which one or more virtual objects are superimposed over a physical environment, or a representation thereof. For example, an electronic system for presenting an AR environment may have a transparent or translucent display through which a person may directly view the physical environment. The system may be configured to present virtual objects on the transparent or translucent display, so that a person, using the system, perceives the virtual objects superimposed over the physical environment. Alternatively, a system may have an opaque display and one or more imaging sensors that capture images or video of the physical environment, which are representations of the physical environment. The system composites the images or video with virtual objects, and presents the composition on the opaque display. A person, using the system, indirectly views the physical environment by way of the images or video of the physical environment, and perceives the virtual objects superimposed over the physical environment. As used herein, a video of the physical environment shown on an opaque display is called “pass-through video,” meaning a system uses one or more image sensor(s) to capture images of the physical environment, and uses those images in presenting the AR environment on the opaque display. Further alternatively, a system may have a projection system that projects virtual objects into the physical environment, for example, as a hologram or on a physical surface, so that a person, using the system, perceives the virtual objects superimposed over the physical environment.

An augmented reality environment also refers to a simulated environment in which a representation of a physical environment is transformed by computer-generated sensory information. For example, in providing pass-through video, a system may transform one or more sensor images to impose a select perspective (e.g., viewpoint) different than the perspective captured by the imaging sensors. As another example, a representation of a physical environment may be transformed by graphically modifying (e.g., enlarging) portions thereof, such that the modified portion may be representative but not photorealistic versions of the originally captured images. As a further example, a representation of a physical environment may be transformed by graphically eliminating or obfuscating portions thereof.

An augmented virtuality (AV) environment refers to a simulated environment in which a virtual or computer-generated environment incorporates one or more sensory inputs from the physical environment. The sensory inputs may be representations of one or more characteristics of the physical environment. For example, an AV park may have virtual trees and virtual buildings, but people with faces photorealistically reproduced from images taken of physical people. As another example, a virtual object may adopt a shape or color of a physical article imaged by one or more imaging sensors. As a further example, a virtual object may adopt shadows consistent with the position of the sun in the physical environment.

There are many different types of electronic systems that enable a person to sense and/or interact with various CGR environments. Examples include head-mounted systems, projection-based systems, heads-up displays (HUDs), vehicle windshields having integrated display capability, windows having integrated display capability, displays formed as lenses designed to be placed on a person's eyes (e.g., similar to contact lenses), headphones/earphones, speaker arrays, input systems (e.g., wearable or handheld controllers with or without haptic feedback), smartphones, tablets, and desktop/laptop computers. A head-mounted system may have one or more speaker(s) and an integrated opaque display. Alternatively, a head-mounted system may be configured to accept an external opaque display (e.g., a smartphone). The head-mounted system may incorporate one or more imaging sensors to capture images or video of the physical environment, and/or one or more microphones to capture audio of the physical environment. Rather than an opaque display, a head-mounted system may have a transparent or translucent display. The transparent or translucent display may have a medium through which light representative of images is directed to a person's eyes. The display may utilize digital light projection, OLEDs, LEDs, uLEDs, liquid crystal on silicon, laser scanning light source, or any combination of these technologies. The medium may be an optical waveguide, a hologram medium, an optical combiner, an optical reflector, or any combination thereof. In one embodiment, the transparent or translucent display may be configured to become opaque selectively. Projection-based systems may employ retinal projection technology that projects graphical images onto a person's retina. Projection systems also may be configured to project virtual objects into the physical environment, for example, as a hologram or on a physical surface.

As described above, one aspect of the present technology is the gathering and use of data available from various sources for use during operation of a head-mounted display device. As an example, such data may identify the user and include user-specific settings or preferences. The present disclosure contemplates that in some instances, this gathered data may include personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For example, a user profile may be established that stores user preference information that allows adjustment of operation of a head-mounted display device according to user preferences. Accordingly, use of such personal information data enhances the user's experience.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of storing a user profile for customizing the user's experience, the present technology can be configured to allow users to select to “opt in” or “opt out” of participation in the collection of personal information data during registration for services or anytime thereafter. In another example, users can select not to provide data regarding usage of specific applications. In yet another example, users can select to limit the length of time that application usage data is maintained or entirely prohibit the development of an application usage profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, user preference information may be determined each time the head-mounted display is used and without subsequently storing the information or associating with the particular user.

What is claimed is:

1. A head-mounted display device, comprising:
a device housing; and
a fan coupled to the device housing and configured to direct airflow within the device housing, the fan including a fan housing, a motor hub, and a fan blade coupled to the motor hub,
wherein the fan blade has a first cross-section adjacent to the motor hub, a second cross-section outward of and adjacent to the first cross-section, and the first cross-section is smaller than the second cross-section such that an applied force to the device housing causes the fan blade to transition from an operable configuration to an inoperable configuration by deformation of the fan blade at the first cross-section.

2. The head-mounted display device according to claim 1, wherein the first cross-section of the fan blade is defined within a first plane perpendicular to a line extending along the fan blade from the motor hub to a tip of the fan blade and the second cross-section of the fan blade is defined within a second plane perpendicular to the line extending along the fan blade from the motor hub to the tip of the fan blade.

3. The head-mounted display device according to claim 1, wherein the fan blade has an upper end positioned near an upper portion of the motor hub and the fan blade is connected to the motor hub adjacent to a lower portion of the motor hub such that the applied force to the device housing is transferred to the upper end of the fan blade to induce rotation of the fan blade around a line extending through the first cross-section.

4. The head-mounted display device according to claim 1, wherein a cross-sectional area of the fan blade at the second cross-section is at least two times a cross-sectional area of the fan blade at the first cross-section.

5. The head-mounted display device according to claim 1, wherein a cross-sectional area of the fan blade at the second cross-section is at least 70 percent of a maximum cross-sectional area of the fan blade.

6. The head-mounted display device according to claim 1, wherein the first cross-section and the second cross-section are located within a first 10 percent of a length of the fan blade as measured from motor hub toward a tip of the fan blade.

7. The head-mounted display device according to claim 1, wherein the fan blade is in the operable configuration when the fan blade rotates within the fan housing to direct airflow within the device housing and the fan blade is in the inoperable configuration when the fan blade cannot rotate to direct airflow within the device housing.

8. The head-mounted display device according to claim 1, wherein the transition from the operable configuration to the inoperable configuration includes separation of the fan blade from the motor hub.

9. The head-mounted display device according to claim 1, wherein the transition from the operable configuration to the inoperable configuration includes the fan blade twisting at the first cross-section.

10. The head-mounted display device according to claim 1, wherein the fan blade is a first fan blade and the fan housing includes a second fan blade coupled to the motor hub, the second fan blade having a narrowed cross-section at a connection between the second fan blade and the motor hub and wherein the first fan blade twists relative to the motor hub at the first cross-section adjacent to the motor hub to the inoperable configuration and the second fan blade twists relative to the motor hub at the narrowed cross-section between the second fan blade and the motor hub to the inoperable configuration in reaction to the applied force to the device housing.

11. The head-mounted display device according to claim 10, wherein the first fan blade nests adjacent to the second fan blade after the first fan blade twists at the first cross-section and the second fan blade twists at the narrowed cross-section.

12. The head-mounted display device according to claim 1, wherein the motor hub includes a side surface including at least one opening such that the motor hub is crushable from a first configuration having a first motor height to a second configuration having a second motor height that is less than the first motor height.

13. The head-mounted display device according to claim 1, wherein the fan housing defines an interior space that includes an air guide member to direct air between an opening in the fan housing and the fan blade and the air guide member is coupled to the fan housing at a first end having a reduced cross-sectional area such that the air guide member is configured to deform to absorb energy of the applied force to the device housing, and the deformation of the air guide member includes at least one of separation of the air guide member from the fan housing, or twisting of the air guide member relative to the fan housing.

14. A head-mounted display device, comprising:
a device housing; and
a fan coupled to the device housing and configured to direct airflow within the device housing, the fan including a fan housing, a motor hub, and a fan blade coupled to the motor hub,
wherein the fan blade has a first cross-section adjacent to the motor hub, a second cross-section outward of and adjacent to the first cross-section, and the first cross-section is smaller than the second cross-section such that an applied force to the device housing causes the fan blade to transition from an operable configuration to an inoperable configuration by deformation of the fan blade at the first cross-section, and
wherein the fan housing includes a sidewall such that the deformation of the sidewall of the fan housing absorbs an energy of the applied force.

15. The head-mounted display device according to claim 14, wherein the sidewall includes a notch extending at least partially through an exterior surface of the fan housing such that a first radial thickness of the sidewall is less than a second radial thickness of the sidewall, and the applied force to the device housing causes the fan housing to deform at the notch from a first configuration in which the fan housing has a first height to a second configuration in which the fan housing has a second height that is less than the first height such that the deformation of the fan housing absorbs an energy of the applied force.

16. The head-mounted display device according to claim 14, wherein the sidewall includes a first portion having a first cross-section and a second portion having a second cross-section that is smaller than the first cross-section and the fan housing is deformable, by pivoting at the second portion, from a first configuration in which the sidewall extends in an axial direction of the fan housing to a second configuration in which the sidewall extends in a direction angled from the axial direction of the fan housing.

17. The head-mounted display device according to claim 14, wherein the sidewall connects an upper fan housing and a lower fan housing, the sidewall including a first angled cutout such that a cross-section of the sidewall varies between the upper fan housing and the lower fan housing such that the upper fan housing rotates and translates relative to the lower fan housing in response to the applied force to the device housing.

18. A head-mounted display device, comprising:
a device housing;
a fan coupled to the device housing and configured to direct airflow within the device housing, the fan including a fan housing, a motor hub, and a fan blade coupled to the motor hub; and
a circuit board coupled to the device housing and adjacent to the fan, the circuit board having an edge defining an opening that is longitudinally aligned with the motor hub of the fan, wherein an applied force to the device housing causes at least part of the motor hub to move from a first position within the fan housing to a second position within the opening in the circuit board.

19. The head-mounted display device according to claim 18, wherein the opening is a recess in the circuit board.

20. The head-mounted display device according to claim 18, wherein the opening extends through the circuit board.
